(19) United States
(12) Patent Application Publication
(10) Pub. No.: US 2026/0237427 A1
(43) Pub. Date: Aug. 13, 2026

(54) Power and Area Efficient Reliable Boosting for Memory Write Assist

(71) Applicant: QUALCOMM Incorporated, San Diego, CA (US)

(72) Inventors: Sant Swaroop SHRIVASTAVA, Noida (IN); Kiran DHAMANE, Sangli (IN); Rahul SAHU, Bangalore (IN)

(21) Appl. No.: 19/051,008

(22) Filed: Feb. 11, 2025

(51) Int. Cl. G11C 11/416; G11C 7/10

(52) U.S. Cl. CPC G11C 11/416; G11C 7/1096

(57) ABSTRACT

A memory is provided with a write driver and negative bit line boost in which a first transistor switches on in response to a first binary value of a boost signal to ground a boost node. During a boost period in which the boost signal has a second binary value, the first transistor switches off while the boost node is boosted to a negative bit line voltage. Another transistor functions to isolate the first transistor from the negative bit line voltage to reduce leakage through the first transistor and thus strengthen the negative bit line boosting.

### TECHNICAL FIELD

This application relates to memories, and more particularly to memories with power and area efficient reliable boosting for memory write assist.

### BACKGROUND

A static random-access memory (SRAM) bitcell stores a data bit through a pair of cross-coupled inverters. Depending upon the binary state of the stored data bit, a p-type metal-oxide semiconductor (PMOS) transistor in one of the cross-coupled inverters charges a data node to a memory power supply voltage. During a write operation in which the binary content of the bitcell is changed, an n-type metal-oxide semiconductor (NMOS) access transistor functions to discharge the same data node while the PMOS transistor continues to charge the data node. The resulting NMOS/PMOS struggle slows the write operation speed and consumes power.

### SUMMARY

In accordance with an aspect of the disclosure, a memory is provided that includes: a boost capacitor; a first transistor coupled between a write driver output node and a first terminal of the boost capacitor, wherein a gate of the first transistor is coupled to a node for a data input signal; a logic gate having a first input terminal coupled to a node for a complement boost signal; a second transistor coupled to the write driver output node, wherein an output terminal of the logic gate is coupled to a gate of the second transistor; and a third transistor coupled between the second transistor and ground, wherein a node for a boost signal is coupled to a gate of the third transistor.

In accordance with another aspect of the disclosure, a negative bit line hybrid boost method is provided that includes: charging a first terminal of a boost capacitor while grounding a second terminal of the boost capacitor through a serial combination of a first transistor, a second transistor, and a third transistor; and discharging the first terminal of the boost capacitor to form a negative bit line boost voltage at the second terminal of the boost capacitor while switching off the second transistor and the third transistor to isolate the second terminal of the boost capacitor from ground and while coupling the second terminal of the boost capacitor through the first transistor to a write driver output node.

Finally, in accordance with yet another aspect of the disclosure, a memory is provided that includes: a boost capacitor having a boost terminal; a first transistor coupled to ground and configured to switch on responsive to a boost signal to ground the boost terminal; a second transistor configured to switch on responsive to a data input signal to couple the boost terminal to a write driver output node; and means for isolating the first transistor from the write driver output node during a boost period in which the boost terminal is boosted to a negative bit line voltage.

These advantage features may be better appreciated by a consideration of the following detailed description.

### BRIEF DESCRIPTION OF THE DRAWINGS

FIG. 1 illustrates a conventional write driver and negative bit line boost circuit.

FIG. 2A illustrates a first write driver and negative bit line boost circuit in accordance with an aspect of the disclosure.

FIG. 2B illustrates a memory including a write driver and negative bit line boost circuit in accordance with an aspect of the disclosure.

FIG. 3 illustrates a modification of the write driver and negative bit line boost circuit of FIG. 2A in which a transistor is included to ground the boost node in accordance with an aspect of the disclosure.

FIG. 4 illustrates a modification of the memory of FIG. 2B in which the second transistors and the corresponding logic gates are disposed in between the write column multiplexer and a remainder of the write driver and negative bit line boost circuit in accordance with an aspect of the disclosure.

FIG. 5 illustrates a modification of the write drive and negative bit line boost circuit of FIG. 4 in which the boost node is grounded through an additional transistor in accordance with an aspect of the disclosure.

FIG. 6 illustrates a modification of the write driver and negative bit line boost circuit of FIG. 2A in which a diode-connected transistor couples between ground and the boost node in accordance with an aspect of the disclosure.

FIG. 7 is a flowchart for a method of negative bit line boosting in accordance with an aspect of the disclosure.

FIG. 8 illustrates some example electronic systems incorporating a memory with negative bit line boosting in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A write operation may involve changing the binary content of a bitcell such that a data node that is being charged by a PMOS transistor in one of the bitcell's cross-coupled inverters must be discharged during the write operation through an NMOS access transistor to a grounded bit line. The faster the NMOS access transistor may discharge the data node, the faster is the memory operating speed. Various forms of write assist may be used to decrease the time necessary for the NMOS access transistor to discharge the data node despite the charging by the PMOS transistor and thus increase the memory speed. One form of write assist for a static random-access memory (SRAM) is known as a negative bit line boost. In a negative bit line boost operation, the grounded bit line is temporarily boosted to a negative voltage during a negative bit line boost period. This negative voltage on the bit line effectively increases the strength of the NMOS access transistor with respect to its struggle with the PMOS transistor that would otherwise continue to charge the data node to a memory power supply voltage. The increased strength of the NMOS access transistor allows it to more quickly discharge the data node so that the write operation speed is increased accordingly. Without the negative bit line boost, the NMOS access transistors may need to be sized larger, which increases the memory footprint on the semiconductor die and thus raises manufacturing costs. But with the negative bit line boost, the NMOS access transistor may be relatively smaller, which decreases the amount of semiconductor die space occupied by the memory and thus lowers manufacturing costs.

To provide the negative boost to the bit line, a memory may include a negative bit line boost circuit with a boost capacitor. The coupling of a negative boost to a bit line from the boost capacitor may occur through a write column multiplexer. During a write operation, the column multiplexer selects for a column of bitcells traversed by a bit line pair. Depending upon the binary value of the bit being written, the boost node in the boost circuit is coupled to one of the bit lines in the bit line pair in the selected column. The boost capacitor has its cathode coupled to a boost node and its anode coupled to a node for the boost signal. With a boost signal in its default charged state, the anode of the boost capacitor is charged to the memory power supply voltage whereas its cathode is grounded, which charges the boost capacitor. During a negative bit line boost period, the boost signal is discharged to ground, which grounds the anode of the boost capacitor. Since the anode was positively charged with respect to the cathode of the boost capacitor, the grounding of the anode causes the cathode to be pulled to a negative voltage. In this fashion, the boost capacitor functions to pull the boost node (and thus the corresponding bit line) to a negative voltage during the boost period.

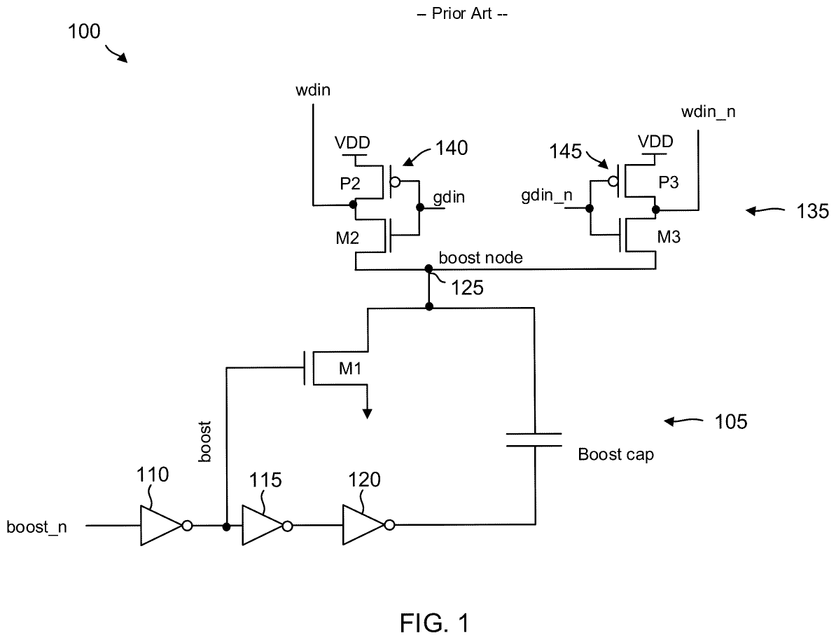

It is convenient for the boost capacitor to be formed by the gate capacitance of a boost transistor. Thus, the following discussion includes implementations in which the boost capacitor may be a boost transistor, but it will be appreciated that a metal-layer boost capacitor may be used in alternative implementations. The negative boosting from the boost capacitor faces a number of challenges that may be better appreciated with a consideration of a portion 100 of a memory as shown in FIG. 1. A negative bit line boost circuit 105 generates a negative bit line boost voltage that is applied to a negative boost node 125 during a negative bit line boost period. A complement (boost_n) of a boost signal that has a default discharged state is inverted by an inverter 110 of the negative bit line boost circuit 105 to form the boost signal (boost) that drives a gate of an n-type metal-oxide semiconductor (NMOS) transistor M1 having a source coupled to ground and a drain coupled to a boost node 125. In its default state, the boost signal is charged to the memory power supply voltage VDD, which switches on transistor M1 to ground the boost node 125. A serial pair of inverters 115 and 120 form a buffer to produce a buffered version of the boost signal to drive an anode of a boost capacitor that has a cathode coupled to the boost node 125. While the boost signal is in its default charged state, the anode of the boost capacitor is charged to memory power supply voltage VDD whereas the cathode of the boost capacitor (the boost node 125) is grounded.

During the negative bit line boost period, a memory controller (not illustrated) asserts the complement boost signal to the memory power supply voltage. The boost signal is thus grounded during the negative bit line boost period to switch off transistor M1 to float the boost node 125. This discharge of the boost signal discharges the anode of the boost capacitor, which causes the boost node 125 to be pulled to a negative voltage due to the previously charged state of the boost capacitor. The boost node 125 functions as a ground node for a write driver 135 that includes an inverter 140 formed by a serial combination of a PMOS transistor P2 and an NMOS transistor M2. The write driver 135 also includes an inverter 145 formed by a serial combination of a PMOS transistor P3 and an NMOS transistor M3. The sources of transistors M2 and M3 couple to the boost node 125. Similarly, the sources of transistors P2 and P3 couple to a node for the memory power supply voltage VDD. The inverter 140 inverts a data input signal gdin to form a write driver input signal wdin at the drains of the transistors P2 and M2. The write driver input signal wdin couples through a write column multiplexer (not illustrated) to a complement bit line (not illustrated) of a selected column as will be explained further herein. Similarly, the inverter 145 inverts a complement data input signal gdin_n to form a complement write driver input signal wdin_n at the drains of transistors P3 and M3. The complement write driver signal wdin_n couples through the write column multiplexer to a bit line (not illustrated) of the selected column.

Suppose that the complement data input signal is a binary one and that the data input signal is a binary zero. Assuming that these true and false binary states are represented using an active-high convention, the transistor M3 will be on such that the bit line coupled to the wdin_n signal is grounded while the boost signal is in its default charged state. When the boost signal is then discharged during the boost period, the bit line coupled to the wdin_n signal will be pulled to a negative bit line boost voltage because the boost node 125 is pulled to an even more negative bit line boost voltage. Should the data input signal instead have a binary true state, it would be the complement bit line that is pulled to the negative bit line voltage. Assuming again that the complement data input signal is true during the boost period, the negative voltage at the drain of transistor M1 (the boost node 125) causes the drain of transistor M1 to effectively function as a source since the grounded gate voltage is acting as a binary one with respect to the negative voltage. Thus, despite the zero at the gate of the transistor M1, transistor M1 is weakly turned on to leak charge from ground through transistor M1 to the boost node 125 and thus weaken the negative boost voltage. At the same time, the transistor M2 has its gate grounded such that it is also nominally off but the negative boost voltage at its source causes the zero at its gate to act as a weak binary one. The transistor M2 will thus also leak charge from the charged complement bit line to the boost node 125 to further weaken the negative boost voltage. Transistors M1 and M3 leak analogously when it is the data input signal that is true during the boost period. The result of this leakage is that the boost capacitor (e.g., a boost transistor) must be relatively large to provide a sufficient negative boost voltage. The resulting larger size of the boost transistor occupies more semiconductor die space and thus increases costs for manufacturing the memory. In addition, the larger gate capacitance from this increased boost transistor size increases the power consumption for the negative bit line boosting.

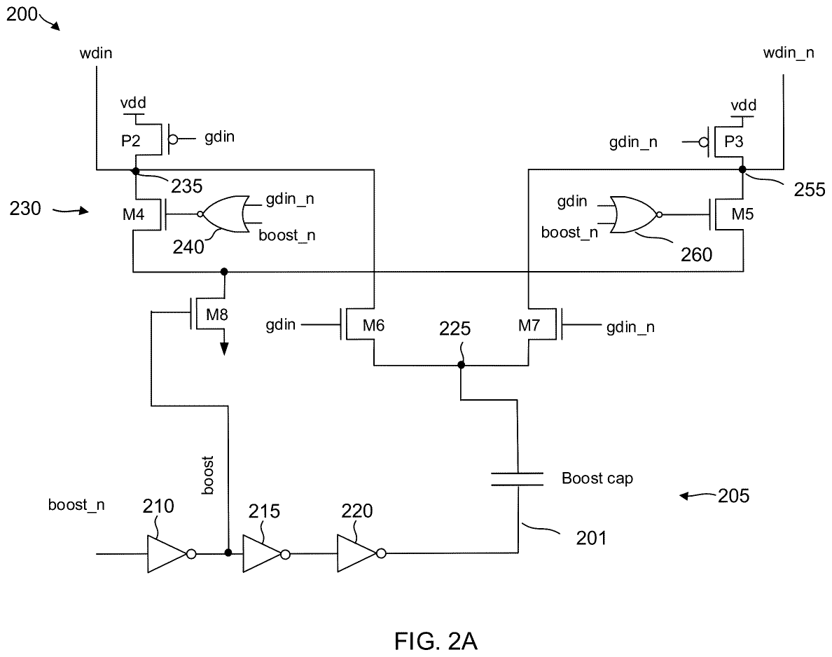

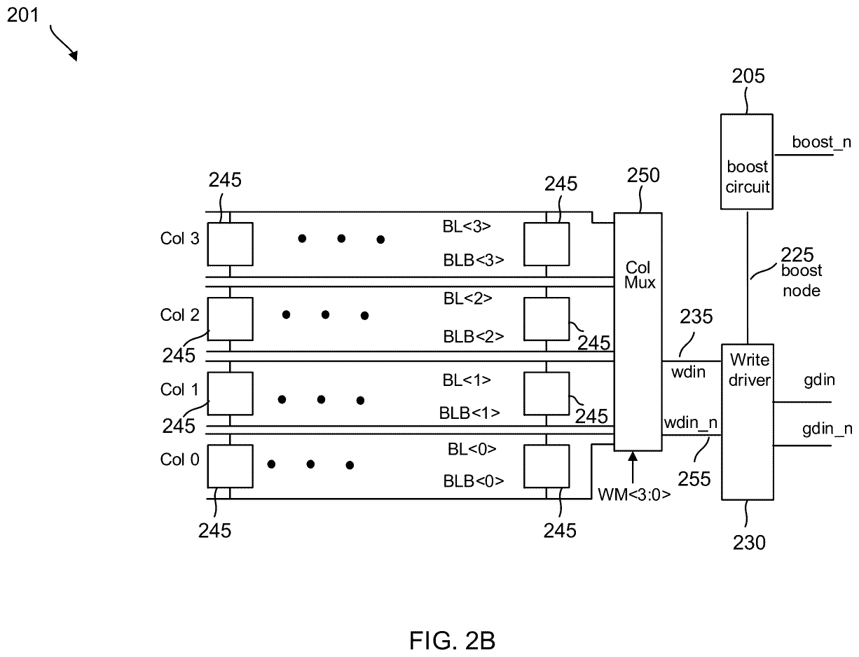

A memory is disclosed herein that alleviates this leakage such that the boost capacitor (e.g., a boost transistor) may be relatively smaller to increase density (i.e., reduce the semiconductor die space demand for the memory) and lower power consumption. A write driver 230 and a negative bit line boost circuit 205 of an example memory are shown in FIG. 2A. As discussed analogously with respect to FIG. 1, negative bit line boost circuit 205 includes a boost capacitor (Boost cap) having a terminal 225 that may also be denoted herein as a boost node 225. An inverter 210 inverts a complement (boost_n) of the boost signal to form the boost signal (boost). A serial pair of inverters 215 and 220 buffers the boost signal to drive a terminal 201 of the boost capacitor. The terminal 225 of the boost capacitor is also denoted herein as a first terminal or a second terminal. Similarly, the terminal 201 of the boost capacitor is also denoted herein as a first terminal or a second terminal. A write driver 230 includes the PMOS transistor P2 having a source coupled to a power supply node for the memory power supply voltage VDD and a drain coupled to a write driver output node 235 for a write driver input signal (wdin). Although the write driver input signal is indeed an output signal from the write driver 230, it is denoted as a write driver input signal as it is an input signal to a write column multiplexer as will be further discussed herein. The data input signal (gdin) drives a gate of the transistor P2. A serial combination of an NMOS transistor M4 and an NMOS transistor M8 couples between the write driver output node 235/drain of transistor P2 and ground. An NMOS transistor M6 couples between the write driver output node 235/drain of transistor P2 and the boost node 225. A node for the boost signal couples to a gate of the transistor M8 so that the transistor M8 is on while the boost signal is in its default charged state. The data input signal drives a gate of the transistor M6. A logic gate such as a NOR gate 240 processes the complement data input signal (gdin_n) with the complement of the boost signal to drive a gate of the transistor M4. Transistor M6 is also denoted herein as a first transistor. Similarly, transistor M4 is also denoted herein as a second transistor whereas the transistor M8 is also denoted herein as a first transistor or a third transistor. In addition, transistor P2 is also denoted herein as a fourth transistor.

The write driver 230 also includes the transistor P3 having a source coupled to the power supply node and a drain coupled to a complement write driver output node 255 for the complement write driver signal (wdin_n). A serial combination of an NMOS transistor M5 and the transistor M8 couples between the complement write driver output node 255 and ground. A logic gate such as a NOR gate 260 NORs the data input signal with the complement of the boost signal to drive a gate of the transistor M5. Transistor M5 will thus be on during the default charged state of the boost signal to discharge the complement write driver output node 255 to ground through the transistor M8 in response to a binary false state of the data input signal. An NMOS transistor M7 also couples between the complement write driver output node 255 and the boost node 225. The complement data input signal drives a gate of the transistor M7 so that transistor M7 will also be on when the complement data input signal is true. Since the transistor M8 is on during the default state of the boost signal, the complement write driver output node 255 and the boost node 225 will discharge to ground through transistor M8 during the default state of the boost signal in response to the complement data input signal being true.

Transistor M4 will be off during the default charged state of the boost signal to discharge the write driver output node 235 in response to a false state of the complement data input signal. The data input signal drives a gate of the transistor M6 so that transistor M6 will also be on when the data input signal is true. During the boost period, the boost signal is discharged to ground to switch off transistor M8 and pull the boost node 225 to the negative bit line voltage and thus pull the complement write driver output node 255 to the negative bit line voltage (assuming that the data input signal is false). The coupling of the negative bit line boost to a bitcell will now be discussed.

A memory 201 including the write driver 230 and the negative bit line boost circuit 205 is shown in more detail in FIG. 2B. For illustration clarity, only a single input/output (IO) group of columns of bitcells 245 is shown in FIG. 2B. A column multiplexer 250 (Col Mux) selects for a column of bitcells 245 during a write operation to couple the complement write driver input signal/complement write driver output node 255 to a bit line in the selected column. Similarly, the column multiplexer 250 couples the write driver input signal/write driver output node 235 to a complement bit line in the selected column. The number of columns multiplexed by the column multiplexer 250 (and thus the number of columns in a single IO) depends upon the memory implementation. In memory 201, column multiplexer 250 selects from four columns of bitcells 245 ranging from a zeroth column (Col 0) to a third column (Col 3) but it will be appreciated that a different IO size may be used in alternative implementations such as two columns or eight columns.

The column multiplexer 250 responds to a column address signal WM<3:0> to select the appropriate column. Each column of bitcells 245 is traversed by a pair of bit lines. For example, a bit line BL<0> and a complement bit line BLB<0> both traverse the length of the zeroth column. Similarly, a bit line BL<1> and a complement bit line BLB<1> traverse the length of a first column (Col 1) whereas a bit line BL<2> and a complement bit line BLB<2> traverse the length of a second column (Col 2). Finally, a bit line BL<3> and a complement bit line BLB<3> traverse the length of the third column. During a write operation, the column multiplexer 250 couples the complement write driver input signal/complement write driver output node 255 to the bit line in the selected column. Referring again to FIG. 2A, the complement write driver output node 255 is grounded prior to the boost period when the data input signal is a binary zero. The bit line in the selected column will thus be discharged whereas the complement bit line stays charged so that a binary zero may be written to the selected bitcell. Similarly, the column multiplexer 250 couples the write driver input signal/write driver output node 235 to the complement bit line in the selected column. The bitcells 245 are also arranged into rows but for illustration clarity only a first row of bitcells 245 and a final row of bitcells 245 are shown in FIG. 2B.

Referring again to FIG. 2A, note that transistor M6 need merely be sized sufficiently to discharge the boost node 225 whereas transistor M8 discharges the selected bit line and may thus be larger than transistor M6. The relatively small size of transistor M6 is advantageous because the strength of the negative bit line boost with respect to a boost capacitance (Cboost) of the boost capacitor may be shown to depend upon a ratio of Cboost to a sum of Cboost with a bit line capacitance, a write driver output node capacitance, and a boost node capacitance. In the negative bit line boost circuit 205, the relatively small size of transistor M6 lowers the write driver output node capacitance and thus increases the strength of the negative bit line boost. In addition, the leakage is reduced because the inverted boost signal is binary one during the boost period, which forces the NOR gate 260 to switch off transistor M5. The negative bit line voltage on the complement write driver output node 255 is thus shielded from the drain of transistor M8, which advantageously reduces the leakage between ground and the boost node 225. With the complement data input signal being a binary one, transistor P2 is on to maintain the charged state of the selected complement bit line. But transistor M4 cannot leak charge to the boost node 225 because there is no negative bit line boost voltage at the source of transistor M4. The leakage to the negative boost node 225 is thus advantageously reduced as compared to the leakage to negative boost node 125. Leakage through transistors M5 and M8 is similarly reduced with respect to a binary true state for the data input signal. The boost capacitor size may thus be reduced yet a sufficient negative boost is provided due to the reduced leakage, which advantageously increases density and reduces power consumption. A combination of the transistor M4 and the NOR gate 240 is an example of a means for isolating the first transistor (e.g., transistor M8) from the write driver output node during a boost period in which the boost terminal is boosted to a negative bit line voltage.

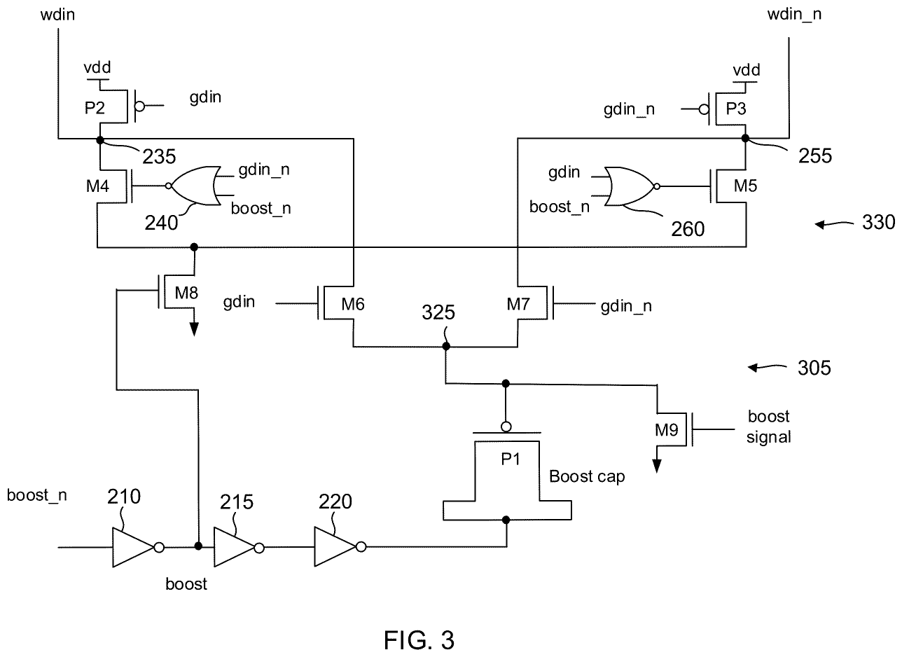

An alternative negative bit line boost circuit 305 and write driver 330 is shown in FIG. 3. Transistors P2, M4, P3, M5, M6, M7, M8, NOR gates 240 and 260, inverters 210, 215, and 220, write driver output node 235, and complement write driver output node 255 are arranged as discussed with respect to FIG. 2A. The negative bit line boost circuit 305 and write driver 330 thus have the advantageously reduced leakage with respect to the negative boosting of a boost node 325 as discussed analogously for the negative boosting of the boost node 225. However, in the negative bit line boost circuit 305, a PMOS boost transistor P1 functions as the boost capacitor (Boost cap). The source and drain of the boost transistor P1 form the anode of the boost capacitor whereas the gate forms the cathode and the boost node 325. A gate capacitance of the boost transistor P1 functions as the boost capacitance. To directly ground the boost node 325 during the default state of the boost signal, an NMOS transistor M9 couples between the boost node 325 and ground. The boost signal drives a gate of the transistor M9 to switch it on and ground the boost node 325 during the default state of the boost signal (prior to the boost period). Transistor M9 thus switches off during the boost period so that the boost node 325 may be pulled to a negative bit line voltage analogously as discussed for the boost node 225. Transistor M9 may be sized relatively small as compared to transistor M8 to advantageously keep the capacitance of the boost node 325 low. Transistor M9 is also denoted herein as a fifth transistor.

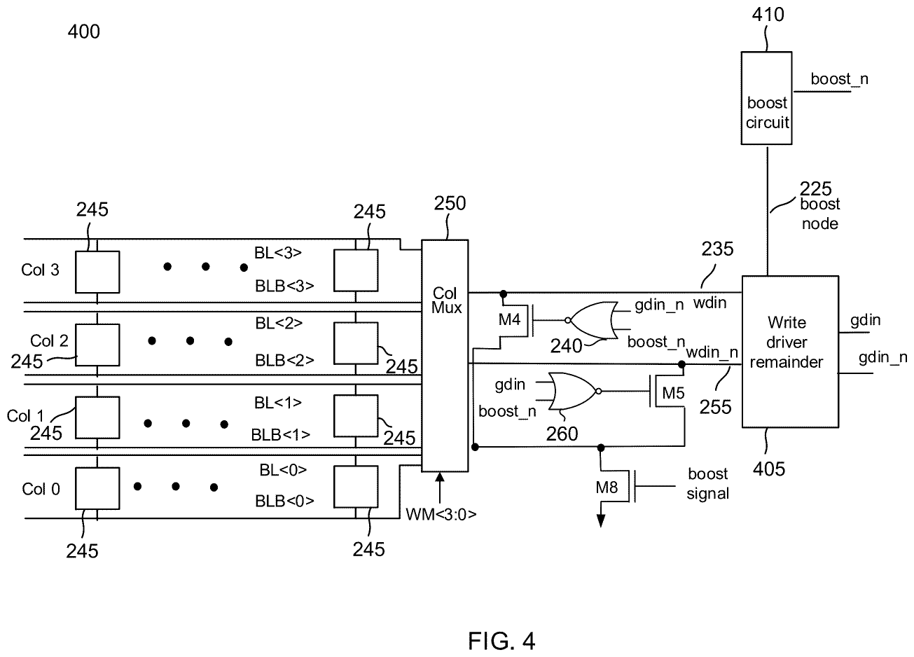

Referring again to FIG. 2B, note that the bit lines are pre-charged prior to a write operation. The function of transistors P2 and P3 in the write driver circuits 230 and 330 is thus merely to maintain the charge of the appropriate ones of the bit lines. In contrast, the transistors M4 and M5 function to discharge the selected bit lines. To assist the strength of this discharge, the transistors M4, M5, M8, and NOR gates 240 and 260 may be positioned closer to the column multiplexer 250 as compared to a remainder 405 of the write driver as shown for a memory 400 in FIG. 4. A negative bit line boost circuit 410 may be arranged as discussed for the negative bit line boost circuit 205 or 305. Similarly, the remainder 405 may be arranged as discussed for the write driver 230 or 330.

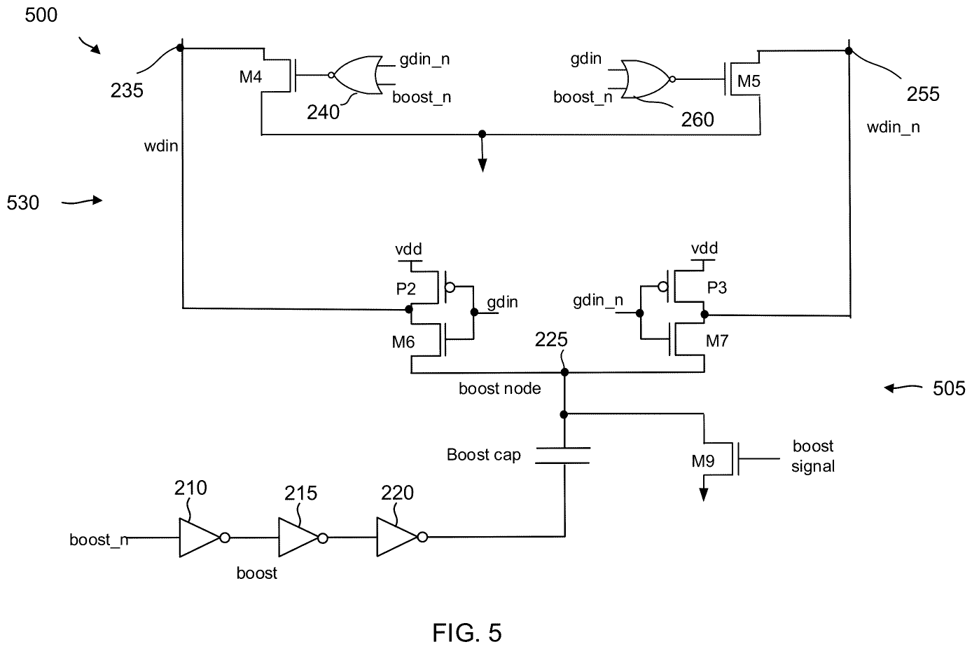

The memory 400 of FIG. 4 may be modified as shown for memory 500 of FIG. 5. A write driver 530 is as discussed with regard to memory 400 except that transistor M8 is eliminated and replaced with a direct coupling between the sources of transistors M4 and M5 and ground. It can be shown that the elimination of transistor M8 may improve the bit line saturation level. A negative bit line boost circuit 505 is analogous to the negative bit line boost circuit 410.

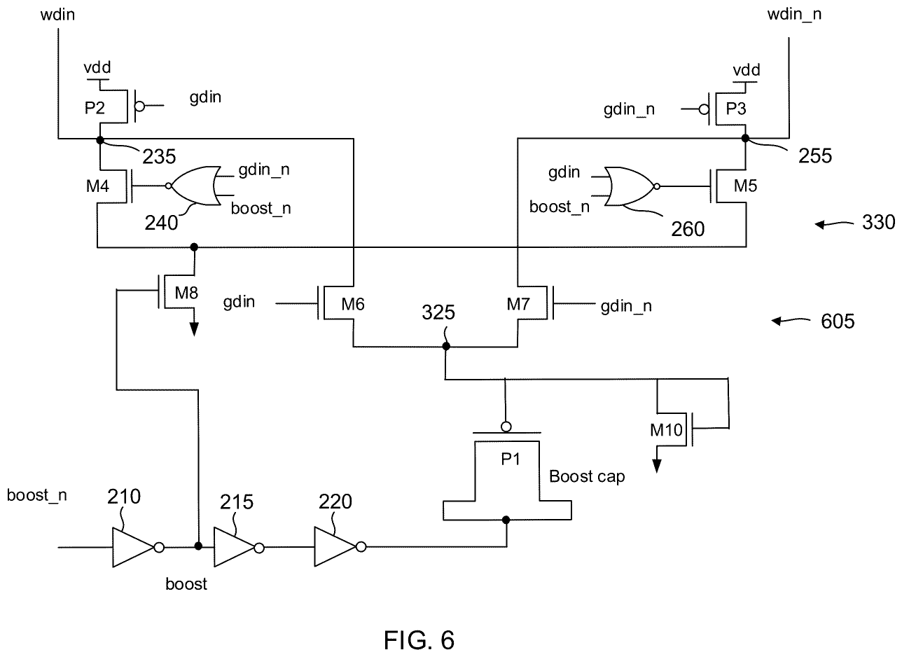

In yet another alternative implementation, the boost node 325 may be coupled to ground through a diode-connected NMOS transistor M10 as shown in FIG. 6 for a negative bit line boost circuit 605 and the write driver 330. The negative bit line boost circuit 605 is arranged as discussed for the negative bit line boost circuit 305 except that transistor M9 is replaced by transistor M10. Transistor M10 prevents the boost node 325 from floating should the boost node 325 get sufficiently charged during non-write-assisted modes of operation.

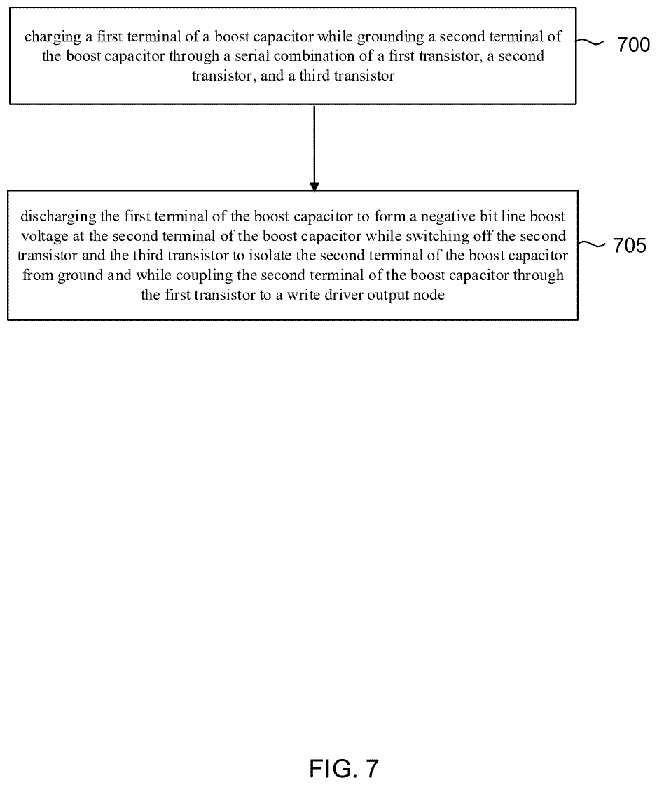

A flowchart for a method of negative bit line boosting is shown in FIG. 7. The method includes an act 700 of charging a first terminal of a boost capacitor while grounding a second terminal of the boost capacitor through a serial combination of a first transistor, a second transistor, and a third transistor. The charging of terminal 201 while the terminal 225 is grounded is an example of act 700. In addition, the method includes an act 705 of discharging the first terminal of the boost capacitor to form a negative bit line boost voltage at the second terminal of the boost capacitor while switching off the second transistor and the third transistor to isolate the second terminal of the boost capacitor from ground and while coupling the second terminal of the boost capacitor through the first transistor to a write driver output node. The coupling of the negative bit line boost voltage through transistor M6 to the write driver output node while transistors M4 and M8 are off is an example of act 705.

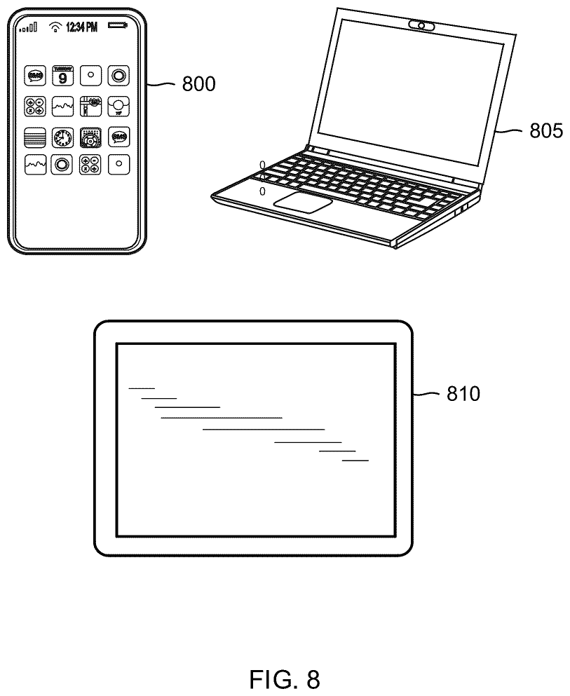

A memory with a negative bit line boost as disclosed herein may be incorporated into a wide variety of electronic systems. For example, as shown in FIG. 8, a cell phone 800, a laptop 805, and a tablet PC 810 may all include a memory configured for a negative bit line boosting as disclosed herein. Other exemplary electronic systems such as a music player, a video player, a communication device, and a personal computer may also be configured with memories constructed in accordance with the disclosure.

The disclosure will now be summarized in the following example clauses:

Clause 1. A memory, comprising:

a boost capacitor;

a first transistor coupled between a write driver output node and a first terminal of the boost capacitor, wherein a gate of the first transistor is coupled to a node for a data input signal;

a logic gate having a first input terminal coupled to a node for a complement of a boost signal;

a second transistor coupled to the write driver output node, wherein an output terminal of the logic gate is coupled to a gate of the second transistor; and

a third transistor coupled between the second transistor and ground, wherein a node for the boost signal is coupled to a gate of the third transistor.

Clause 2. The memory of clause 1, wherein the logic gate includes a second input terminal coupled to a node for a complement of the data input signal.

Clause 3. The memory of any of clauses 1-2, wherein the logic gate comprises a NOR gate.

Clause 4. The memory of any of clauses 1-3, further comprising:

a fourth transistor coupled between a node for a memory power supply voltage and the write driver output node, wherein a gate of the fourth transistor is coupled to the node for the data input signal.

Clause 5. The memory of clause 4, wherein the first transistor is an n-type metal-oxide semiconductor (NMOS) transistor, the second transistor is an NMOS transistor having a drain coupled to the write driver output node, the third transistor is an NMOS transistor having a source coupled to ground and a drain coupled to a source of the second transistor, and the fourth transistor is a p-type metal-oxide semiconductor transistor having a drain coupled to the write driver output node and a source coupled to the node for the memory power supply voltage.

Clause 6. The memory of any of clauses 1-5, wherein the memory includes:

a write column multiplexer configured to couple the write driver output node to a selected column of bitcells from a plurality of columns of bitcells.

Clause 7. The memory of clause 6, wherein the write column multiplexer is further configured to couple the write driver output node to a complement bit line in the selected column of bitcells.

Clause 8. The memory of any of clauses 1-7, further comprising:

an inverter configured to invert a complement of the boost signal to form the boost signal; and

a buffer having an input terminal coupled to the node for the boost signal and an output terminal coupled to a second terminal of the boost capacitor.

Clause 9. The memory of any of clauses 1-8, wherein the boost capacitor comprises a gate capacitance of a boost transistor.

Clause 10. The memory of clause 9, wherein the boost transistor is a PMOS transistor.

Clause 11. The memory of any of clauses 1-10, wherein a size of the first transistor is smaller than a size of the third transistor.

Clause 12. The memory of clause 6, wherein the logic gate and the second transistor are disposed between a remainder of the write driver and negative bit line boost circuit and the write column multiplexer.

Clause 13. The memory of any of clauses 1-12, further comprising:

a fifth transistor coupled between the first terminal of the boost capacitor and ground, wherein a gate of the fifth transistor is coupled to the node for the boost signal.

Clause 14. The memory of any of clauses 1-12, further comprising:

a diode-connected transistor coupled between the first terminal of the boost capacitor and ground.

Clause 15. The memory of any of clauses 1-14, wherein the memory is included within a cellular telephone.

Clause 16. A negative bit line boost method, comprising:

charging a first terminal of a boost capacitor while grounding a second terminal of the boost capacitor through a serial combination of a first transistor, a second transistor, and a third transistor; and

discharging the first terminal of the boost capacitor to form a negative bit line boost voltage at the second terminal of the boost capacitor while switching off the second transistor and the third transistor to isolate the second terminal of the boost capacitor from ground and while coupling the second terminal of the boost capacitor through the first transistor to a write driver output node.

Clause 17. The negative bit line boost method of clause 16, further comprising:

coupling the negative bit line boost voltage from the write driver output node through a write column multiplexer to a bit line of a selected column of bitcells.

Clause 18. The negative bit line boost method of clause 17, further comprising:

inverting a complement of a boost signal to form a boost signal; and

buffering the boost signal to charge the first terminal of the boost capacitor.

Clause 19. A memory, comprising:

a boost capacitor having a boost terminal;

a first transistor coupled to ground and configured to switch on responsive to a boost signal to ground the boost terminal;

a second transistor configured to switch on responsive to a data input signal to couple the boost terminal to a write driver output node; and

means for isolating the first transistor from the write driver output node during a boost period in which the boost terminal is boosted to a negative bit line voltage.

Clause 20. The memory of clause 19, further comprising:

a diode-connected transistor coupled between the boost terminal and ground.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A memory, comprising:
a boost capacitor;
a first transistor coupled between a write driver output node and a first terminal of the boost capacitor, wherein a gate of the first transistor is coupled to a node for a data input signal;
a logic gate having a first input terminal coupled to a node for a complement of a boost signal;
a second transistor coupled to the write driver output node, wherein an output terminal of the logic gate is coupled to a gate of the second transistor; and
a third transistor coupled between the second transistor and ground, wherein a node for the boost signal is coupled to a gate of the third transistor.

2. The memory of claim 1, wherein the logic gate includes a second input terminal coupled to a node for a complement of the data input signal.

3. The memory of claim 2, wherein the logic gate comprises a NOR gate.

4. The memory of claim 1, further comprising:
a fourth transistor coupled between a node for a memory power supply voltage and the write driver output node, wherein a gate of the fourth transistor is coupled to the node for the data input signal.

5. The memory of claim 4, wherein the first transistor is an n-type metal-oxide semiconductor (NMOS) transistor, the second transistor is an NMOS transistor having a drain coupled to the write driver output node, the third transistor is an NMOS transistor having a source coupled to ground and a drain coupled to a source of the second transistor, and the fourth transistor is a p-type metal-oxide semiconductor (PMOS) transistor having a drain coupled to the write driver output node and a source coupled to the node for the memory power supply voltage.

6. The memory of claim 4, wherein the memory includes:
a write column multiplexer configured to couple the write driver output node to a selected column of bitcells from a plurality of columns of bitcells.

7. The memory of claim 6, wherein the write column multiplexer is further configured to couple the write driver output node to a complement bit line in the selected column of bitcells.

8. The memory of claim 1, further comprising:
an inverter configured to invert the complement of the boost signal to form the boost signal; and
a buffer having an input terminal coupled to the node for the boost signal and an output terminal coupled to a second terminal of the boost capacitor.

9. The memory of claim 1, wherein the boost capacitor comprises a gate capacitance of a boost transistor.

10. The memory of claim 9, wherein the boost transistor is a PMOS transistor.

11. The memory of claim 1, wherein a size of the first transistor is smaller than a size of the third transistor.

12. The memory of claim 6, wherein the logic gate and the second transistor are disposed between a remainder of the write driver and negative bit line boost circuit and the write column multiplexer.

13. The memory of claim 1, further comprising:
a fifth transistor coupled between the first terminal of the boost capacitor and ground, wherein a gate of the fifth transistor is coupled to the node for the boost signal.

14. The memory of claim 1, further comprising:
a diode-connected transistor coupled between the first terminal of the boost capacitor and ground.

15. The memory of claim 1, wherein the memory is included within a cellular telephone.

16. A negative bit line boost method, comprising:
charging a first terminal of a boost capacitor while grounding a second terminal of the boost capacitor through a serial combination of a first transistor, a second transistor, and a third transistor; and
discharging the first terminal of the boost capacitor to form a negative bit line boost voltage at the second terminal of the boost capacitor while switching off the second transistor and the third transistor to isolate the second terminal of the boost capacitor from ground and while coupling the second terminal of the boost capacitor through the first transistor to a write driver output node.

17. The negative bit line boost method of claim 16, further comprising:
coupling the negative bit line boost voltage from the write driver output node through a write column multiplexer to a bit line of a selected column of bitcells.

18. The negative bit line boost method of claim 17, further comprising:
inverting a complement of a boost signal to form a boost signal; and
buffering the boost signal to charge the first terminal of the boost capacitor.

19. A memory, comprising:
a boost capacitor having a boost terminal;
a first transistor coupled to ground and configured to switch on responsive to a boost signal to ground the boost terminal;
a second transistor configured to switch on responsive to a data input signal to couple the boost terminal to a write driver output node; and
means for isolating the first transistor from the write driver output node during a boost period in which the boost terminal is boosted to a negative bit line voltage.

20. The memory of claim 19, further comprising:
a diode-connected transistor coupled between the boost terminal and ground.
